(19) United States
(12) Patent Application Publication
(10) Pub. No.: US 2014/0159157 A1
(43) Pub. Date: Jun. 12, 2014

(54) ANTENNA DIODE CIRCUITRY AND METHOD OF MANUFACTURE

(71) Applicant: Altera Corporation, (US)

(72) Inventors: Bradley Jensen, San Jose, CA (US); Shue Ling Ong, Kuala Sepetang (MY); Dustin Do, Milpitas, CA (US); Wuu-Cherng Lin, San Jose, CA (US)

(73) Assignee: Altera Corporation, San Jose, CA (US)

(21) Appl. No.: 13/708,556

(22) Filed: Dec. 7, 2012

(51) Int. Cl. H01L 27/088; H01L 29/66

(52) U.S. Cl. CPC H01L 27/088; H01L 29/66477
USPC 257/368; 438/294; 438/299

(57) ABSTRACT

An integrated circuit with an antenna diode is described. The integrated circuit includes a substrate, a transistor, first and second diffusion regions, and a dummy gate. The transistor and the first and second diffusion regions may be formed within the substrate. The transistor has its gate structure disposed on the substrate. The dummy gate structure may be disposed on a region of the substrate such that it separates the first diffusion region from the second diffusion region. The dummy gate structure may also be coupled to the transistor gate structure.

### BACKGROUND

Antenna effect is a phenomenon that occurs during manufacturing of an integrated circuit. This phenomenon may occur when a substantial amount of electrical charge that is generated as a result of certain semiconductor manufacturing processes flows through a transistor structure into a semiconductor substrate, thereby causing gate oxide breakdown. The antenna effect therefore decreases yield and causes reliability issues for an integrated circuit.

Antenna diodes are often utilized to mitigate the antenna effect. Typically, an antenna diode is inserted into a region on an integrated circuit that is prone to antenna effect. Locations at which the antenna diodes are formed may be determined through an antenna violation check that is governed by antenna design rules. The antenna design rules may depend on the current state of the art process technology node.

The design and size of the antenna diode have remained relatively the same over a number of process generations. However, with newer process nodes, inserting antenna diodes on integrated circuit devices has become significantly more challenging. In order to include an antenna diode on an integrated circuit, substantial alterations (some or all of which may need to be performed manually) may need to be made to the layout of the integrated circuit. Compared to other functional circuitry, antenna diodes may also occupy a disproportionately large area on the integrated circuit.

It is within this context that the embodiments described herein arise.

### SUMMARY

Embodiments described herein include antenna diode circuitry and a method to manufacture the antenna diode circuitry. It should be appreciated that the embodiments can be implemented in numerous ways, such as a process, an apparatus, a system, a device, or a method. Several embodiments are described below.

In one embodiment, an antenna diode circuitry structure that may overcome antenna effect in an integrated circuit is disclosed. The antenna diode may serve to discharge any accumulated charge (e.g., charge built up on the surface of a conductive trace) to ground. The antenna diode does not require additional area within the integrated circuit as it utilizes layout area adjacent to a dummy gate. Furthermore, the antenna diode may be readily formed on the integrated circuit layout as it does not require significant alterations to the layout.

In one embodiment, an integrated circuit with an antenna diode is described. The integrated circuit may include a substrate, a transistor, first and second diffusion regions, and a dummy gate. The transistor and the first and second diffusion regions may be formed in the substrate. The transistor has an associated gate structure disposed on the substrate. The dummy gate structure may be disposed on a region of the substrate such that the dummy gate structure separates the first diffusion region from the second diffusion region. The dummy gate structure may also be coupled to the transistor gate structure.

In an alternative embodiment, another integrated circuit with an antenna diode is described. The integrated circuit includes a substrate, a transistor, an antenna diode and a dummy gate structure. The transistor and the antenna diode are formed on the substrate. The dummy gate structure is formed in such that it extends over the antenna diode circuitry on the substrate.

In another embodiment, a method of forming an integrated circuit with an antenna diode is described. The method includes forming a dummy gate structure on a substrate. After forming the dummy gate structure, the method includes implanting dopants into the substrate to form a pair of diffusion regions in the substrate. The pair of diffusion regions may be formed immediately adjacent to the dummy gate structure.

In an alternative embodiment, another method to manufacture an integrated circuit having an antenna diode is described. The method includes forming a transistor gate structure and a plurality of dummy gate structures. The transistor gate structure and the plurality of dummy gate structures may be located close to each other. Furthermore, the plurality of dummy gate structures may be parallel to the transistor gate structure. The method further includes forming at least a first diffusion region pair immediately adjacent to the transistor gate structure and at least a second diffusion region pair immediately adjacent to a selected one of the dummy gate structures. Furthermore, the method includes forming a conductive path that couples the transistor gate structure and at least one of the diffusion regions of the second diffusion region pairs.

Further features of the invention, its nature and various advantages will be more apparent from the accompanying drawings and the following detailed description of the preferred embodiments.

### BRIEF DESCRIPTION OF THE DRAWINGS

FIG. 1 shows an illustrative integrated circuit (IC) having antenna diode circuitry in accordance with one embodiment of the present invention.

FIG. 2 shows an implementation of antenna diode circuitry in accordance of one embodiment of the present invention.

FIG. 3 shows cross-sectional side view of the antenna diode circuitry of FIG. 2 in accordance with one embodiment of the present invention.

FIG. 4 shows a method of designing an antenna diode on an integrated circuit in accordance with one embodiment of the present invention.

FIG. 5 shows another implementation of antenna diode circuitry in accordance of one embodiment of the present invention.

FIG. 6 shows a cross-sectional side view of the antenna diode circuitry of FIG. 3 in accordance with one embodiment of the present invention.

FIG. 7 shows a method of manufacturing antenna diode circuitry in accordance with one embodiment of the present invention.

### DETAILED DESCRIPTION

The following embodiments describe antenna diode circuitry and a method to manufacture the antenna diode circuitry. It will be recognized, however, by one skilled in the art, that the present exemplary embodiments may be practiced without some or all of these specific details. In other instances, well-known operations have not been described in detail in order not to unnecessarily obscure the present embodiments.

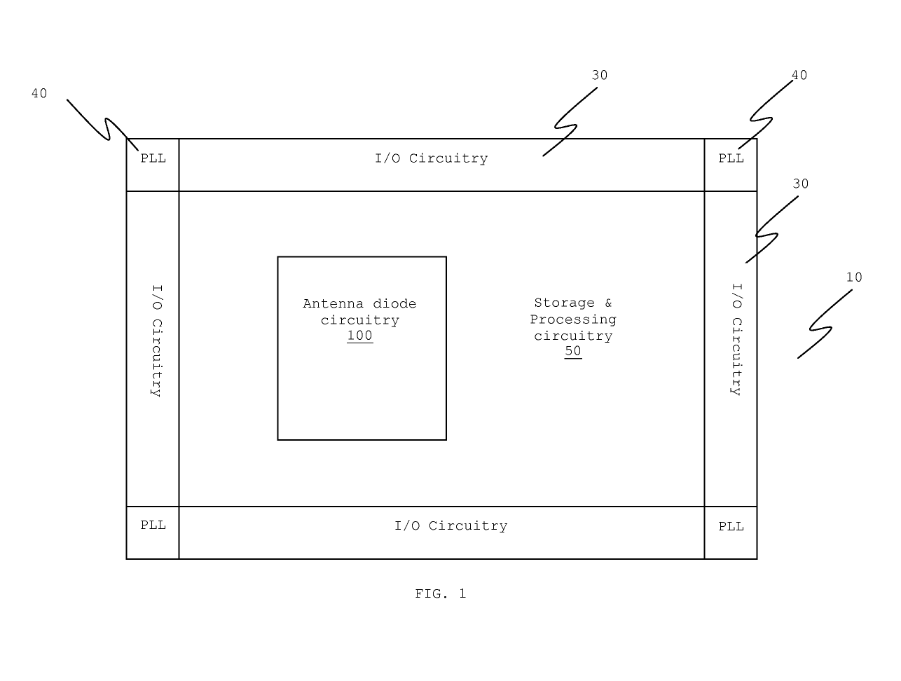

FIG. 1, meant to be illustrative and not limiting, illustrates an integrated circuit (IC) 10 in accordance with one embodiment of the present invention. Integrated circuit 10 may include at least input/output (I/O) circuitry 30, storage and processing circuitry 50, and phase-locked loop (PLL) circuitry 40. In one embodiment, these circuitries may be arranged on an IC (e.g., IC 10) as illustrated in FIG. 1.

Integrated circuit 10, in one instance, may be a programmable logic device (PLD) such as a field programmable gate array (FPGA) device. It should be appreciated that PLDs may be programmed or configured to include customized circuit designs. This provides advantages over fixed design integrated circuits (e.g., application specific integrated circuits (ASICs)). In one embodiment, a PLD (e.g., IC 10) may include programmable logic elements configured to perform any of a variety of functions. In one instance, the programmable logic elements may be configured as storage and processing circuitry 50.

Still referring to FIG. 1, I/O circuitry 30 may be placed at the periphery of IC 10. I/O circuitry 30 may couple internal circuitry of IC 10 (e.g., storage and processing circuitry 50) to external circuitry via I/O pads connected to pins on an IC package. To avoid over-complicating FIG. 1, details of the I/O circuitry 30 are not shown.

Referring still to the embodiment of FIG. 1, each corner of IC 10 may include PLL circuitry 40. Phase-locked loop circuitry 40 may be used for generates clock signals with different respective frequencies. Each PLL 40 may output a signal that has a relatively stable frequency, together with low frequency spurs and good phase noise. The output signals from respective PLLs 40 may be transmitted to circuits within IC 10 or to external circuitry that may be coupled to IC 10.

In the embodiment of FIG. 1, storage and processing circuitry 50 may occupy a relatively large area on IC 10. In one embodiment, storage and processing circuitry 50 may include a plurality of storage elements such as memory circuitry, registers and/or latches that may be utilized for storing/retrieving data. Storage and processing circuitry 50 may also include processing circuitry such as flip-flops, multiplexers and/or interconnects that may be utilized to perform arithmetic or conversion functions on received signals.

The circuits in storage and processing circuitry 50 may be formed by a plurality of transistors. Each transistor may include a gate electrode and source and drain diffusion regions. Storage and processing circuitry 50 may also include antenna diode circuitry 100, as shown in the embodiment of FIG. 1. Antenna diode circuitry 100 may be utilized for design-for-manufacturability (DFM) purposes. In one embodiment, antenna diode circuitry 100 may be utilized to overcome antenna effects when transistors are formed within storage and processing circuitry 50.

It should be appreciated that antenna effects may occur during a wafer manufacturing process, especially during the manufacturing of metal pathways on metal layers. For example, electrostatic charge may be generated because of the relatively large friction on the metal pathways generated by the chemical mechanical polishing (CMP) process. If the accumulated charge is large enough, it may flow through the transistor into the substrate and damage gate oxide material that is formed underneath the gate of the transistor. The flow of chargethrough the transistor may also damage PN junctions (e.g., junctions at which P-type regions and N-type regions meet).

Accordingly, antenna diode circuitry 100 may serve as a safe discharge pathway for the electrostsatic charge. In one embodiment, antenna diode circuitry 100 may be placed near the gate of the transistor. Automated computer-aided design (CAD) tools may be used to design antenna diode circuitry 100 according to specific antenna design rules.

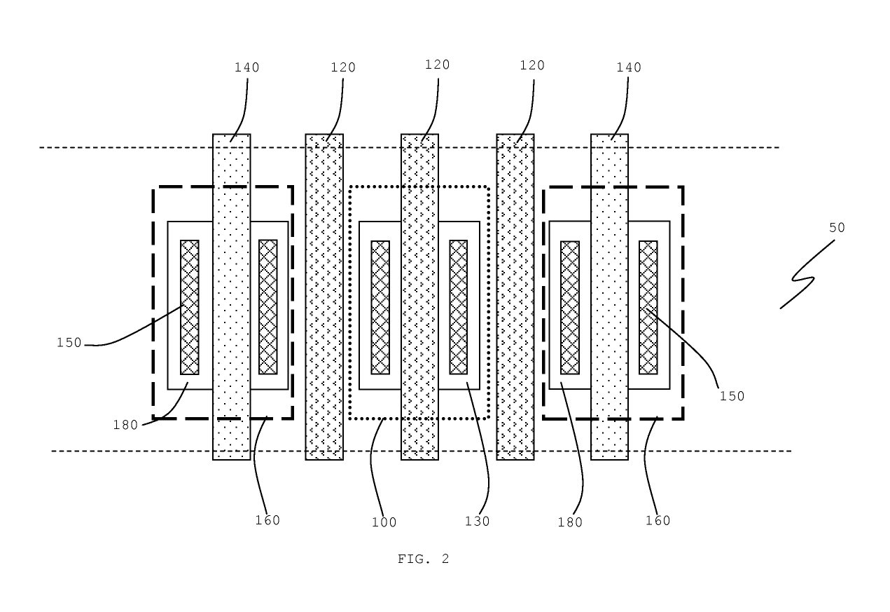

FIG. 2, meant to be illustrative and not limiting, illustrates a top view of storage and processing circuitry 50 in accordance with one embodiment of the present invention. Storage and processing circuitry 50 includes antenna diode circuitry 100 surrounded by two transistor structures 160. There may also be at least one dummy gate structure 120 between the respective transistor structure 160 and antenna diode circuitry 100.

Antenna diode circuitry 100 may include dummy gate structure 120, a pair of diffusion regions 130 and interconnects 150. Dummy gate structure 120 may be an electrode formed over a substrate of an integrated circuit. In one embodiment, dummy gate structure 120 may not be coupled to any power source or circuits and may be at a floating voltage level. Dummy gate structure 120 may also be formed as part of the DFM requirements. Accordingly, dummy gate structure 120 may be composed of similar material as transistor gate structure 140. In one instance, the material may be polycrystalline silicon (polysilicon).

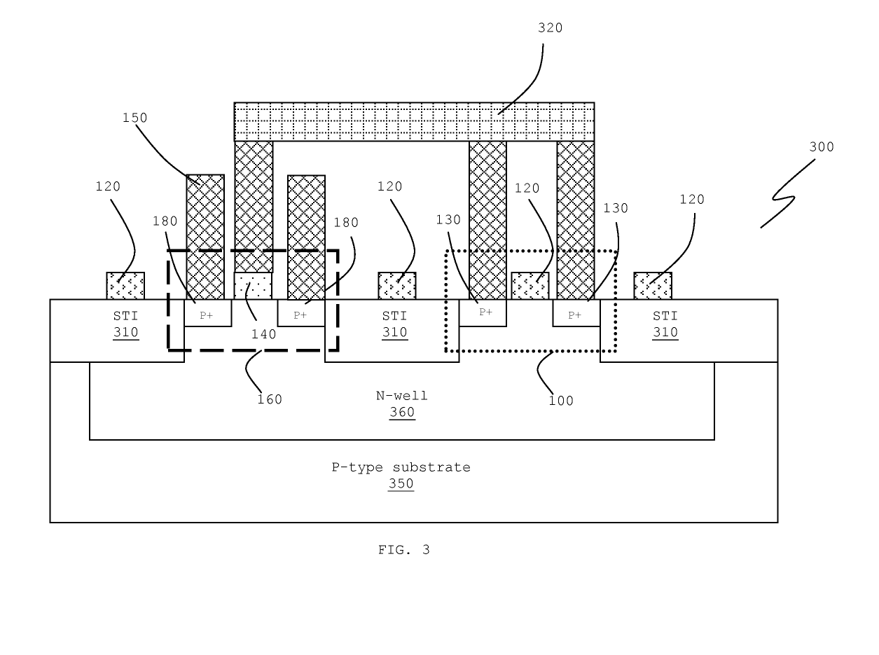

Still referring to FIG. 2, the pair of diffusion regions 130 may be formed immediately adjacent to dummy gate structure 120. Diffusion regions 130 may provide safe discharge pathways for the built-up charge on the metal pathways (e.g., metal pathways 320, the details of which will be described in reference to FIG. 3).

In one embodiment, the size of each of diffusion regions 130 depends on the amount of charge that needs to be discharged. As described in FIG. 1, the amount of charge that builds up may depend on a number of factors (e.g., the amount of built up charge may depend on how much of the metal pathway is exposed to the CMP process). It should be appreciated that if a big portion of the metal pathway is exposed to the process, the amount of charge that is built up will increase. Therefore, under such circumstances, a relatively large diffusion region 130 may be needed within antenna diode circuitry 100.

Referring still to the embodiment of FIG. 2, diffusion region 130 may be doped using P-type dopants when diffusion region 130 is surrounded by an N-well region. Accordingly, diffusion region 130 may be doped using N-type dopants when diffusion region 130 is surrounded by a P-type substrate region. It should be appreciated that even though a rectangular diffusion region (e.g., diffusion region 130) is shown within antenna diode circuitry 50, diffusion regions of different shapes may be applicable in this context.

In the embodiment of FIG. 2, each of transistor structures 160 may include gate structure 140, source-drain regions 180, and interconnects 150. Gate structure 140 may function as a gate to allow electrical current to propagate between source-drain regions 180. In one instance, electrical current may propagate from the source region (e.g., the left portion of source-drain region 180 with reference to gate structure 140) to drain region (e.g., the right portion of source-drain region 180 with reference to gate structure 140) when gate structure 140 is supplied with voltage. It should be appreciated that gate structure 140 may be coupled to other circuits in the integrated circuit that supplies the gate voltage. In one embodiment, gate structure 140 may be composed of polysilicon material.

As shown in FIG. 2, source-drain regions 180 may be located immediately adjacent to gate structure 140. In one instance, source-drain regions 180 are located on the left and right side of gate structure 140, similar to diffusion region 130 that is located on the left and right side of dummy gate structure 120. Furthermore, source-drain regions 180 may also be implanted with P+ or N+ dopants similar to diffusion region 130. In one embodiment, source-drain regions 180 may be P-doped when the surrounding region of source-drain regions 130 is an N-well region. In another embodiment, source-drain regions 180 may be N-doped when the surrounding region of source-drain regions 130 is a p-substrate region. It should be appreciated that the implanting of source-drain regions 180 may be performed simultaneously with the implanting of diffusion region 130.

In the embodiment of FIG. 2, interconnects 150 may couple diffusion region 130 with source-drain regions 180. In one embodiment, interconnects 150 may be a plurality of conductive vias that couples metal pathways (e.g., metal pathways 320 of FIG. 3) on a metal layer to diffusion region 130 or source-drain regions 180.

FIG. 3, meant to be illustrating and not limiting, shows a cross-sectional view of an integrated circuit 300 in accordance with an embodiment of the present invention. As shown in FIG. 3, integrated circuit 300 may include antenna diode circuitry 100 and transistor structure 160. IC 300 may be manufactured on a p-type silicon substrate 350. It should be appreciated that even though a P-type silicon substrate (e.g., P-type silicon substrate 350) may be one of the more commonly available substrates, other substrates (e.g., N-type silicon substrate, SiGe substrate, etc.) may be used in this context.

Referring still to FIG. 3, N-well 360 may be formed within P-type silicon substrate 350. It shall be appreciated that N-well 360 may be manufactured using a diffusion process of N-type dopants into P-type silicon substrate 350. Source-drain regions 180 of transistor structure 160 and diffusion regions 130 of antenna diode circuitry 100 may be formed within N-well region 360. Shallow trench isolation (STI) 310 may also be formed within N-well region 360.

Shallow trench isolation 310 may be placed between transistor structure 160 and antenna diode circuitry 100. In one embodiment, STI 310 may also be formed on perimeter of transistor structure 160 and antenna diode circuitry 100. STI 310 may provide isolation between active structures (e.g., transistor structure 160 and antenna diode circuitry 100).

Referring still to FIG. 3, dummy gate structure 120 may be disposed over STI 310. Dummy gate structure 120 may be utilized to manufacture transistor gate structure 140 within a process critical dimension. It should be appreciated that the critical dimension of a semiconductor device (e.g., IC 300) may be defined as the smallest geometrical dimension that may be formed for a particular process node.

Referring still to the embodiment of FIG. 3, interconnects 150 may be coupled to either diffusion regions 130 or source-drain regions 180. Interconnects 150 may include an interconnect that provides a connection from metal pathway 320 to diffusion regions 130 and may include another interconnect that provides a connection from source-drain region 180 to metal pathway 320.

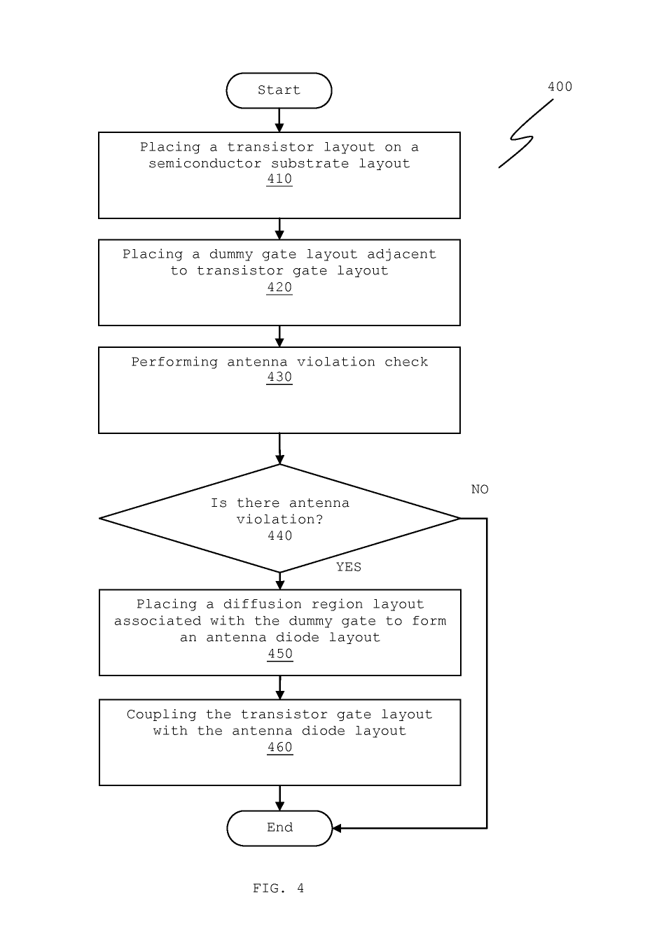

FIG. 4, meant to be illustrative and not limiting, shows a method 400 of designing an antenna diode circuitry on an integrated circuit in accordance with one embodiment of the present invention. In one embodiment, method 400 may be performed by a CAD tool. At step 410, a transistor structure is formed on a substrate. The transistor structure may be similar to the top-view of transistor structure 160 in FIG. 2. The transistor structure may include a gate, a drain, and a source. In one embodiment, the transistor structure may be part of the circuit of storage & processing circuitry 50 in FIG. 1.

At step 420, a dummy gate structure is placed adjacent to the transistor structure. In one embodiment, the dummy gate structure may be similar to the top-view of dummy gate structure 120 in FIG. 2. It should be appreciated that the insertion of dummy gate structure may be for DFM purposes (i.e., for the formation of transistors gate within critical dimensions). For example, at the 20 nanometer (nm) process node, there may be at least two dummy gate structures on each side (i.e., left and right sides) of the transistor gate structure.

At step 430, an antenna violation check is performed. It should be appreciated that antenna violation checks may be performed based on antenna rules that may be utilized to identify the probability of antenna effects. It should be appreciated that the antenna rules may take into account different factors. In one embodiment, the antenna rules may take into account the ratio between an area that includes the gate and an exposed area that includes the metal pathways. It should be appreciated that the antenna violation check may be performed by a CAD tool.

At step 440, it is determined whether there is an antenna violation through antenna violation checks. When there is no violation, method 400 ends. However, when there is an antenna violation based on the given antenna rules, method 400 moves on to step 450. At step 450, an antenna diode circuit may be created by placing a diffusion region adjacent to the layout of the dummy gate structure. Therefore, the diffusion region layout may be associated with the layout of the dummy gate structure. The diffusion region and the dummy gate structure may be similar to the top-view of diffusion regions 130 and dummy gate 120 of FIG. 2. The antenna diode circuitry may be similar to top-view of antenna diode circuitry 100 of FIG. 2.

Finally at step 460, the transistor gate structure is coupled to the diffusion region of the antenna diode circuitry. In one embodiment, the layout for the transistor gate structure is coupled to the diffusion region through a conductive pathway. The conductive pathway may include interconnects 150 and metal pathways 320 of FIG. 3.

It should be appreciated that after step 460, the integrated circuit may include a transistor structure and an antenna diode circuitry. In one embodiment, the layout may be similar to that shown in the embodiment of FIG. 2.

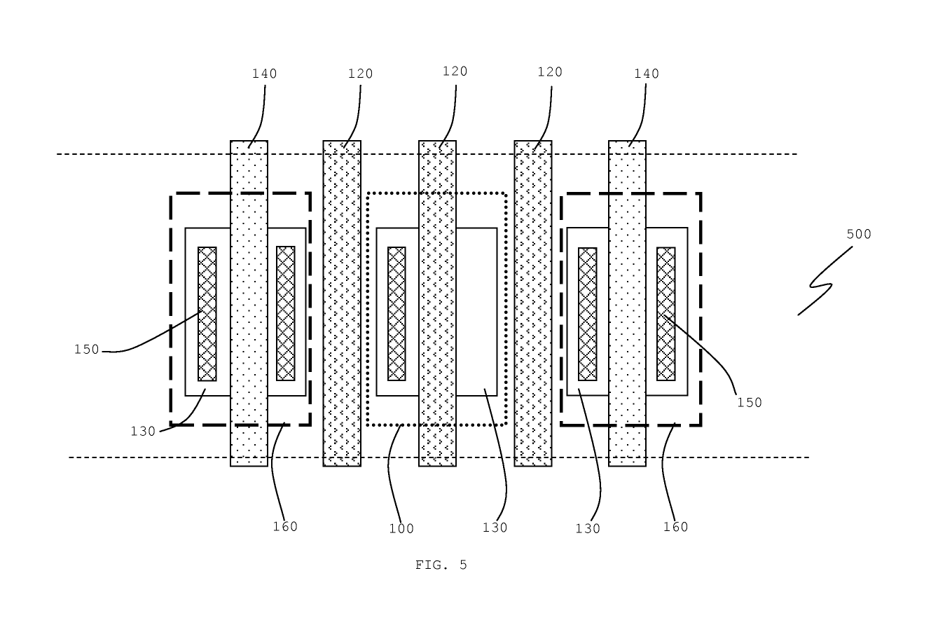

FIG. 5, meant to be illustrative and not limiting, shows a top-view of an integrated circuit 500 in accordance with one embodiment of the present invention. It should be appreciated that integrated circuit 500 shares similarities with integrated circuit 200 of FIG. 2 and as such, for the sake of brevity, elements that have been described above (e.g., transistor structure 160 and antenna diode circuitry 100) may not be described in detail again. In the embodiment of FIG. 5, one side (e.g., either the right or left side) of diffusion regions 130 within antenna diode circuitry 100 may not include interconnects 150.

According to one embodiment, absence of interconnects 150 from one side of diffusion region 130 provides a greater flexibility for manufacturing metal pathways compared to layout structure 200 of FIG. 2 as space may be limited on an integrated circuit.

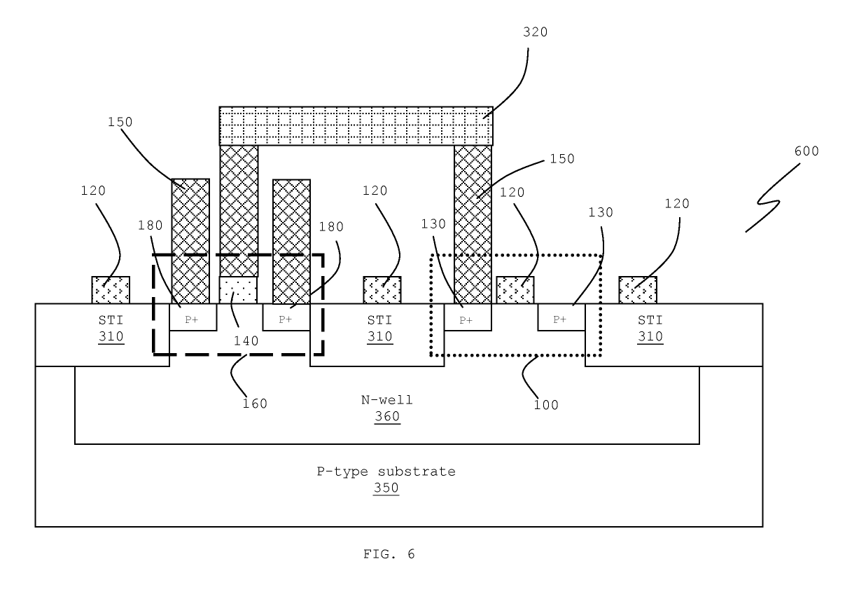

FIG. 6, meant to be illustrative and not limiting, illustrates a cross-sectional view of integrated circuit 600 in accordance with one embodiment of the present invention. Integrated circuit 600 may share similarities with integrated circuit 500 of FIG. 5. Accordingly, integrated circuit 600 may include transistor structure 160 and antenna diode circuitry 100. Integrated circuit 600 may also share similarities with integrated circuit 300 of FIG. 3 and as such, for the sake of brevity, elements that have been described above (e.g., transistor structure 160 and antenna diode circuitry 100) are not described in detail again. In the embodiment of FIG. 6, there may be no interconnects (e.g., interconnects 150) on one side (e.g., the right diffusion region 130) of antenna diode circuitry 100. Hence, this may provide the flexibility to build other connections that for integrated circuit 600.

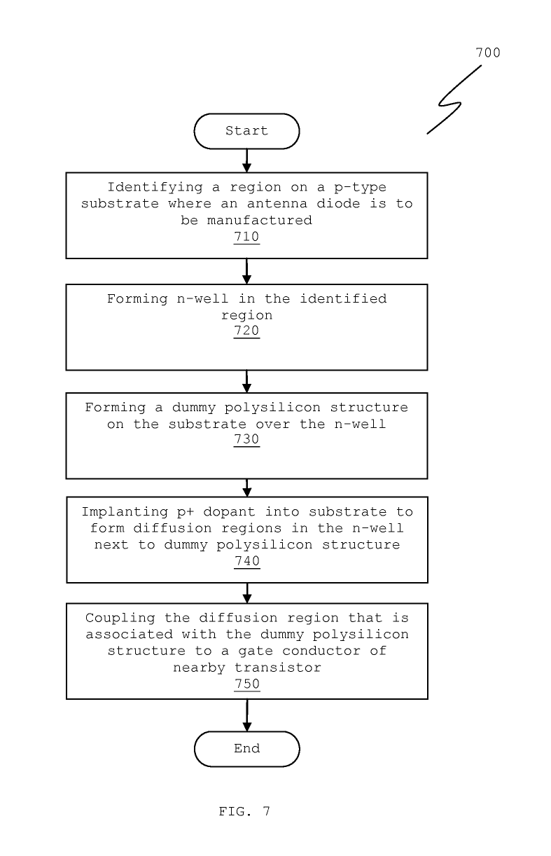

FIG. 7, meant to be illustrative and not limiting, illustrates a method of manufacturing an integrated circuit in accordance with one embodiment of the present invention. In one embodiment, method 700 may be used to manufacture an integrated circuit (e.g., integrated circuit 200 of FIG. 2 or integrated circuit 500 of FIG. 5). It should be appreciated, that other well-known process steps may not be discussed in detail here.

At step 710, a region on a P-type silicon substrate is identified. The antenna diode circuitry may be formed on that region. In one embodiment, the antenna diode circuitry may be similar to antenna diode circuitry 100 of FIGS. 3 and 6. The region may be selected based on different factors. As an example, a region where multiple transistors are formed, which may be prone to antenna effect, may be selected.

At step 720, an N-well is formed on the identified region. The N-well may be formed by a diffusion of N-type dopants. In one embodiment, the N-well is similar to N-well 360 of FIG. 3 and FIG. 6. It should be appreciated that the N-well may substantially fill the selected region.

Subsequently, at step 730, a dummy polysilicon is formed on the substrate over the N-well. In one embodiment, the dummy polysilicon may be similar to dummy gate structure 120 of FIGS. 3 and 5. The dummy polysilicon may be formed using a deposition process (e.g., a low pressure chemical-vapor deposition (LPCVD) process). In one embodiment, step 730 may be performed concurrently with the formation of the transistor gate structure (e.g., transistor gate structure 140 of FIGS. 3 and 6).

At step 740, P+ dopants are implanted into the substrate to form diffusion regions within the N-well. The implanted regions may be immediately adjacent to the dummy polysilicon. It should be appreciated that during the implantation process, the region on the substrate that is exposed to P+ dopants may include the dummy polysilicon region and regions adjacent to the dummy polysilicon. However, only the regions adjacent to the dummy polysilicon may be implanted with P+ dopants. In one embodiment, the resulting implanted regions may be similar to diffusion regions 130 in FIGS. 3 and 6.

At step 750, the diffusion region that is associated with the dummy polysilicon is coupled to the gate of a nearby transistor. In one embodiment, the diffusion region may be coupled to the gate through conductive pathways (e.g., metal pathways 320 and interconnects 150 of FIGS. 3 and 5, respectively). It should be appreciated that the coupling of the diffusion region with the gate of the transistor may reduce antenna effect. In one embodiment, as illustrated in FIG. 3, two diffusion regions may be coupled to the gate of the transistor. In another embodiment, as illustrate in FIG. 6, only one single diffusion region may be coupled to the gate of the transistor.

The embodiments thus far have been described with respect to integrated circuits. The methods and apparatuses described herein may be incorporated into any suitable circuit. For example, they may be incorporated into numerous types of devices such as programmable logic devices, application specific standard products (ASSPs), and application specific integrated circuits (ASICs). Examples of programmable logic devices include programmable arrays logic (PALs), programmable logic arrays (PLAs), field programmable logic arrays (FPGAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The programmable logic device described in one or more embodiments herein may be part of a data processing system that includes one or more of the following components: a processor; memory; IO circuitry; and peripheral devices. The data processing can be used in a wide variety of applications, such as computer networking, data networking, instrumentation, video processing, digital signal processing, or any suitable other application where the advantage of using programmable or re-programmable logic is desirable. The programmable logic device can be used to perform a variety of different logic functions. For example, the programmable logic device can be configured as a processor or controller that works in cooperation with a system processor. The programmable logic device may also be used as an arbiter for arbitrating access to a shared resource in the data processing system. In yet another example, the programmable logic device can be configured as an interface between a processor and one of the other components in the system. In one embodiment, the programmable logic device may be one of the family of devices owned by ALTERA Corporation.

Although the methods of operations were described in a specific order, it should be understood that other operations may be performed in between described operations, described operations may be adjusted so that they occur at slightly different times or described operations may be distributed in a system which allows occurrence of the processing operations at various intervals associated with the processing, as long as the processing of the overlay operations are performed in a desired way.

Although the foregoing invention has been described in some detail for the purposes of clarity, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims.

The foregoing is merely illustrative of the principles of this invention and various modifications can be made by those skilled in the art without departing from the scope and spirit of the invention.

1. An integrated circuit, comprising:
a substrate;
a transistor formed in the substrate, wherein the transistor includes a transistor gate structure disposed on the substrate and between transistor diffusion regions;
first and second diffusion regions that are formed in the substrate; and
a dummy gate structure disposed on a region in the substrate, wherein a region on which the dummy gate structure is disposed separates the first diffusion region from the second diffusion region, and wherein the first diffusion region is coupled to the transistor gate structure.

2. The integrated circuit defined in claim 1, wherein the first and second diffusion regions are formed immediately adjacent to the region in the substrate on which the dummy gate structure is disposed.

3. The integrated circuit defined in claim 1, wherein the second diffusion region is coupled to the transistor gate structure, and wherein the first and second diffusion regions serve as antenna diode circuitry for the transistor.

4. The integrated circuit defined in claim 1, further comprising:
shallow trench isolation structures formed in the substrate between the transistor and the first and second diffusion regions.

5. The integrated circuit defined in claim 4, further comprising:
an additional dummy gate structure formed on the shallow trench isolation structures.

6. The integrated circuit defined in claim 1, further comprising:
at least one additional dummy gate structure formed on the substrate between the transistor gate structure and the dummy gate structure.

7. The integrated circuit defined in claim 1, wherein the dummy gate structure comprises a floating polysilicon gate structure.

8. The integrated circuit defined in claim 1, wherein the first and second diffusion regions comprises substrate material having a first doping type, and wherein the region separating the first diffusion region from the second diffusion region comprises substrate material having a second doping type that is different than the first doping type.

9. An integrated circuit, comprising:
a substrate;
a transistor formed in the substrate;
antenna diode circuitry formed in the substrate; and
a dummy gate structure that extends over the antenna diode circuitry on the substrate.

10. The integrated circuit defined in claim 9, wherein the transistor includes a gate, wherein the antenna diode circuitry includes a plurality of diffusion regions formed in the substrate, and wherein at least one diffusion region in the plurality of diffusion regions in the antenna diode circuitry is coupled to the gate.

11. The integrated circuit defined in claim 9, wherein the transistor includes a gate, wherein the antenna diode circuitry includes a pair of diffusion regions formed in the substrate, and wherein each diffusion region in the pair of diffusion regions in the antenna diode circuitry is coupled to the gate.

12. The integrated circuit defined in claim 9, wherein the transistor includes a gate, wherein the antenna diode circuitry includes a pair of diffusion regions formed in the substrate, wherein at least one diffusion region in the pair of diffusion regions in the antenna diode circuitry is coupled to the gate, wherein the pair of diffusion regions have a first doping type, and wherein the pair of diffusion regions are separated by a region in the substrate that is covered by the dummy gate structure and has a second doping type that is different than the first doping type.

13. The integrated circuit defined in claim 9, further comprising:
shallow trench isolation structures formed in the substrate between the transistor and the antenna diode circuit; and
at least one additional dummy gate structure formed on the shallow trench isolation structures.

14. The integrated circuit defined in claim 9 further comprising another transistor, wherein both the transistors comprise a gate, wherein the antenna diode circuitry includes a plurality of diffusion regions formed in the substrate, and wherein at least one diffusion region in the plurality of diffusion regions in the antenna diode circuitry is coupled to the gates.

15-22. (canceled)

23. An integrated circuit, comprising:
a substrate;
a transistor formed on the substrate; and
electrostatic discharge circuitry that is formed on the substrate and that includes a conductive structure that is permanently disposed on the substrate.

24. The integrated circuit defined in claim 23, wherein the conductive structure of the electrostatic discharge circuitry is electrically floating.

25. The integrated circuit defined in claim 23, wherein the electrostatic discharge circuitry comprises:
at least one diffusion region formed in the substrate immediate adjacent to the conductive structure.

26. The integrated circuit defined in claim 25, wherein the transistor includes a transistor gate structure, and wherein the transistor gate structure is directly coupled to the at least one diffusion region of the electrostatic discharge circuitry.

27. The integrated circuit defined in claim 26, further comprising:
a shallow trench isolation structure that is formed in the substrate and that is interposed between the transistor and the electrostatic discharge circuitry.

28. The integrated circuit defined in claim 27, further comprising:
an additional conductive structure on the shallow trench isolation structure.

29. The integrated circuit defined in claim 28, wherein the conductive structure, the additional conductive structure, and the transistor gate structure are formed from the same material.

30. The integrated circuit defined in claim 23, further comprising:
an additional transistor formed on the substrate, wherein the transistor has a first channel region in the substrate, wherein the additional transistor has a second channel region in the substrate, and wherein the conductive structure is formed directly over a region in the substrate that is interposed between the first and second channel regions.
